(19) United States
(12) Patent Application Publication
(10) Pub. No.: US 2020/0178404 A1
(43) Pub. Date: Jun. 4, 2020

(54) FLEXIBLE DISPLAY DEVICE

(71) Applicant: Samsung Display Co., Ltd., Yongin-si (KR)

(72) Inventor: Min Ho UM, Yongin-si (KR)

(21) Appl. No.: 16/563,220

(22) Filed: Sep. 6, 2019

(30) Foreign Application Priority Data
Nov. 29, 2018 (KR) 10-2018-0150813

(51) Int. Cl. H05K 5/00; H01L 51/52; H05K 5/02; G06F 3/14

(52) U.S. Cl. CPC H05K 5/0017; H01L 51/5237; H01L 27/3244; G06F 3/14; H05K 5/0226

(57) ABSTRACT

A flexible display device includes a flexible display panel configured to display an image; a driving module unit configured to transfer a driving signal to the flexible display panel and that is detachably fixedly coupled to at least a first side of the flexible display panel; and a panel bending unit coupled to at least a second side of the flexible display panel, wherein the panel bending unit includes a plurality of coupling parts fixedly coupled to the flexible display panel; and a plurality of joint parts between the plurality of coupling parts and having a hinged multi-jointed structure.

### CROSS-REFERENCE TO RELATED APPLICATION

This application claims priority to and the benefit of Korean Patent Application No. 10-2018-0150813, filed in the Korean Intellectual Property Office on Nov. 29, 2018, the entire contents of which are incorporated herein by reference.

### BACKGROUND

### 1. Field

Embodiments of the present disclosure relate to a flexible display device.

### 2. Description of Related Art

With regard to display devices, interest in display devices that are larger and clearer is growing, as is interest in display devices that are easy to move and store. A flexible display device is formed of a flexible display panel that includes a plurality of pixels on a flexible substrate such as a plastic film, rather than a rigid substrate, and has a bending property. Such a flexible display device may be used for various purposes because the flexible display device may be bent by applying a force to transform the shape of the flexible display device.

### SUMMARY

An exemplary embodiment of the present disclosure provides a flexible display device including a detachable driving module unit.

Another exemplary embodiment of the present disclosure provides a flexible display device further including a multi-jointed supporter.

A flexible display device according to an exemplary embodiment of the present disclosure includes a flexible display panel configured to display an image; a driving module unit configured to transfer a driving signal to the flexible display panel and that is detachably fixedly coupled to at least a first side of the flexible display panel; and a panel bending unit coupled to at least a second side of the flexible display panel, wherein the panel bending unit includes a plurality of coupling parts fixedly coupled to the flexible display panel; and a plurality of joint parts between the plurality of coupling parts and having a hinged multi-jointed structure.

In addition, the plurality of coupling part may be attached to the flexible display panel using an adhesive.

In addition, the plurality of joint parts may be adjacent to the flexible display panel as the plurality of coupling parts are coupled to the flexible display panel.

In addition, each of the plurality of joint parts may include a plurality of supporters; and a hinge coupling part, wherein the supporters that are adjacent to each other are coupled to each other by the hinge coupling part, and wherein the hinge coupling part includes a link arm that extends from a side of one of the supporters to the adjacent supporter; and a plurality of fixing pins that hinge and pass through the link arm of the adjacent supporters.

In addition, the driving module unit may include at least one hardware module selected from speakers, microphones, cameras, infrared (IR) lamps and sensors.

In addition, the driving module unit may include a first magnet on one side thereof to be coupled to the flexible display panel, and wherein the flexible display panel includes a second magnet that is on a first side coupled to the driving module unit and has a polarity opposite to that of the first magnet.

In addition, the driving module unit may be configured to sense a bending and disposal state of the flexible display panel based on a sensing signal received from the flexible display panel.

In addition, the driving module unit may control the flexible display panel such that a different image is displayed in a first region and a second region divided by a first axis when the flexible display panel is bent along the first axis.

In addition, the driving module unit may control the flexible display panel such that an application content image is displayed on a front of the flexible display panel when the flexible display panel is bent along a second axis and forms a predetermined angle with respect to a ground.

A flexible display device according to an exemplary embodiment of the present disclosure has a detachable driving module unit, such that the flexible display device may be easily stored and carried when not in use.

### BRIEF DESCRIPTION OF THE DRAWINGS

The accompanying drawings, together with the specification, illustrate embodiments of the subject matter of the present disclosure, and, together with the description, serve to explain principles of embodiments of the subject matter of the present disclosure.

FIG. 1 is a schematic cross-sectional view showing a structure of a flexible display panel according to an exemplary embodiment of the present disclosure.

FIG. 2 is an enlarged view of a portion of a flexible display panel shown in FIG. 1.

FIG. 3 is a perspective view of a flexible display device according to a first exemplary embodiment of the present disclosure.

FIG. 4 is an exploded perspective view of a flexible display device according to a first exemplary embodiment of the present disclosure.

FIG. 5 is an enlarged cross-sectional view of a portion of a flexible display device according to a first exemplary embodiment of the present disclosure.

FIG. 6 is a perspective view showing a first use state of a flexible display device according to a first exemplary embodiment of the present disclosure.

FIG. 7 is a front view showing a second usage state of a flexible display device according to a first exemplary embodiment of the present disclosure.

FIG. 8 is a plan view of a flexible display device according to the second exemplary embodiment of the present disclosure.

FIGS. 9 and 10 are partial enlarged views of a panel bending unit shown in FIG. 8.

FIG. 11 is a perspective view showing an example of a bending state of a flexible display device according to a second exemplary embodiment of the present disclosure.

### DETAILED DESCRIPTION

It will be apparent to those skilled in the art that various modifications and variations can be made to the subject matter of the present disclosure without departing from the spirit or scope of the disclosure, and certain embodiments are exemplified in the drawings and explained in the detailed description. Thus, it is intended that the present disclosure covers the modifications and variations of the subject matter of the present disclosure that fall within the scope of the present disclosure and their equivalents.

Like reference numerals designate like elements throughout the specification. In the accompanying drawings, dimensions of structures may be exaggerated for clarity. The terms, ‘first’, ‘second’ and the like may be simply used for description of various constituent elements, but those meanings may not be limited to the restricted meanings. The above terms are used only for distinguishing one constituent element from other constituent elements. For example, a first constituent element may be referred to as a second constituent element and similarly, the second constituent element may be referred to as the first constituent element within the scope of the appended claims. When explaining the singular, unless explicitly described to the contrary, it may be interpreted as the plural meaning.

In the present specification, the word “comprise” or “has” is used to specify existence of a feature, a numbers, a process, an operation, a constituent element, a part, or a combination thereof, and it will be understood that existence or additional possibility of one or more other features or numbers, processes, operations, constituent elements, parts, or combinations thereof are not excluded in advance. In addition, it will be understood that when an element such as a layer, film, region, or substrate is referred to as being “on” another element, it can be directly on the other element or intervening elements may also be present. In the present specification, it will be understood that when an element such as a layer, film, region, or substrate is referred to as being “on” another element, the direction in which the element is arranged is not limited to an upper direction and may include a side direction or a lower direction instead. In contrast, It will be understood that when an element such as a layer, film, region, or substrate is referred to as being “beneath” another element, it can be directly beneath the other element or intervening elements may also be present.

Hereinafter, an exemplary embodiment of the present disclosure will be described with reference to drawings related to the present disclosure.

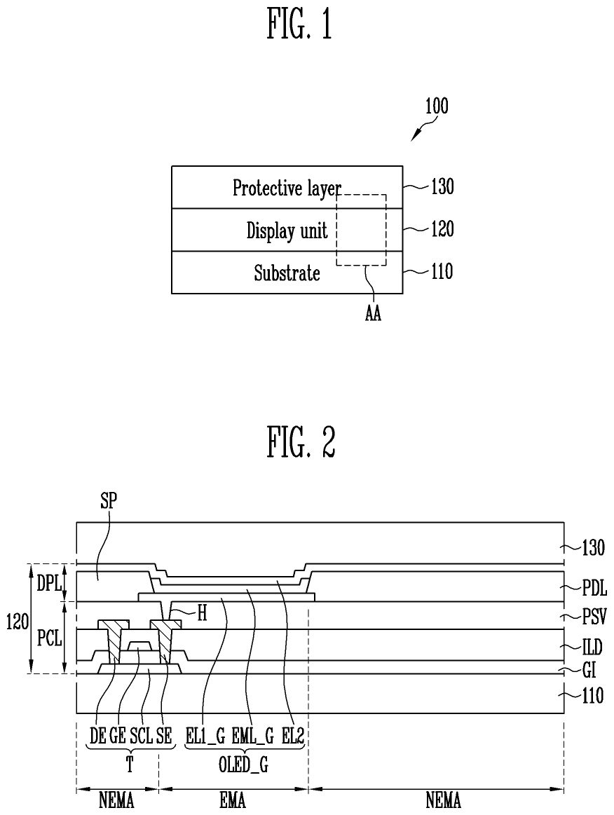

FIG. 1 is a drawing showing a structure of a flexible display panel according to an exemplary embodiment of the present disclosure.

Referring to FIG. 1, the flexible display panel 100 may include a substrate 110, a display unit 120, and a protective layer 130.

The substrate 110 may be formed of a flexible material that may be transformed by an external force. For example, the substrate 110 may be formed of a plastic substrate (e.g., a polymer film). In an exemplary embodiment of the present disclosure, the substrate 110 may have a structure in which a barrier coating is applied to both sides of a base material. The base material may be formed of various suitable resins such as polyimide (PI), polycarbonate (PC), polyethyleneterephthalate (PET), polyethersulfone (PES), polyethylene naphthalate (PEN) and fiber reinforced plastic (FRP). The barrier coating is performed on mutually facing surfaces of the base material, and an organic film or an inorganic film may be used to maintain flexibility. In addition, the substrate 110 may be formed of a material having flexibility such as a thin glass or a metal foil in addition to a plastic substrate.

The display unit 120 may include a plurality of pixels. Each pixel may be formed of a pixel circuit to drive a pixel and an organic light emitting diode (OLED). Each pixel of the display unit 120 may display an image by emitting light in response to driving signals received from a driving module unit 200 described later.

The protective layer 130 may be provided to protect the display unit 120. The protective layer 130 may be formed of an inorganic layer, an organic layer, or a composite laminate in which the inorganic layer and the organic layer are alternately stacked. The inorganic layer may include at least one selected from SiO₂, SiNₓ, SiON, Al₂O₃, TiO₂, Ta₂O₅, HfO₂, ZrO₂, BST, PZT or the like. The organic layer may include at least one selected from a general purpose polymer (PMMA, PS), a polymer derivative having a phenol group, an acrylic polymer, an imide polymer, an aryl ether polymer, an amide polymer, a fluorine polymer, a p-xylene polymer, a vinyl alcohol polymer, blends thereof, or the like. The protective layer 130 may be formed of a transparent film to cover the entire surface of the display unit 120.

The structure of the flexible display panel 100 is merely an example, and the technical features of the present disclosure are not limited thereto. For example, the flexible display panel 100 may further include a touch sensor, a window cover, and/or the like. In addition, the flexible display panel 100 may further include a protective film configured to protect a lower portion of the substrate 110 as well as the protective layer 130 provided on the display unit 120.

In addition, the flexible display panel 100 may further include a transformation sensing module, a resistance sensing module, and a pressure sensing module configured to sense a bending (or folding) state of the flexible display panel 100. These modules may be mounted in the form of a circuit element to the display unit 120 of the flexible display panel 100. In addition, these modules may sense the bending state of the flexible display panel 100 based on resistance changes, pressure changes, etc. in the flexible display panel 100. The flexible display panel 100 may generate a sensing signal corresponding to the sensed bending state and transfer the sensing signal to the outside.

FIG. 2 is an enlarged view of a portion of a flexible display panel shown in FIG. 1. For example, FIG. 2 is an enlarged view of the area AA of FIG. 1.

Referring to FIG. 2, the flexible display panel 100 may include a substrate 110, a display unit 120 on the substrate, and a protective layer 130.

The substrate 110 may include a transparent insulation material to transmit light. In addition, the substrate 110 may be a flexible substrate. The flexible substrate may include a film substrate and a plastic substrate including a polymeric organic material.

A display unit 120 including a pixel may be formed on the substrate 110. The pixel may include a first pixel R, a second pixel G, and a third pixel B configured to emit light of different colors. In an exemplary embodiment of the present disclosure, the first pixel R may include a red pixel configured to emit red light, the second pixel G may include a green pixel configured to emit green light, and the third pixel B may include a blue pixel configured to emit blue light.

Each of the first to third pixels R, G, and B may include a pixel circuit unit PCL and a display element layer DPL having light emitting element connected (e.g., coupled) to the pixel circuit unit PCL.

The pixel circuit unit PCL may include at least one transistor T provided on the substrate 110 and a passivation layer PSV provided on the transistor T.

The transistor T may include a semiconductor layer SCL, a gate electrode GE, a source electrode SE and a drain electrode DE.

A semiconductor layer SCL may be provided on the substrate 110. The semiconductor layer SCL may include source and drain regions that are in contact with the source electrode SE and the drain electrode DE, respectively. A region between the source region and the drain region may be a channel region.

The semiconductor layer SCL may be a semiconductor pattern formed of at least one selected from polysilicon, amorphous silicon, oxide semiconductor, or the like. The channel region may be a semiconductor pattern doped with an impurity. The impurity may be an impurity such as n-type impurity, p-type impurity, or other metal.

The gate electrode GE may be provided on the semiconductor layer SCL with a gate insulation layer GI therebetween.

The source electrode SE and the drain electrode DE included in the transistor T may be connected (e.g., coupled) to the source region and the drain region of the semiconductor layer SCL through a contact hole passing through an interlayer insulation layer ILD and the gate insulation layer GI, respectively.

The passivation layer PSV may cover the transistor T and protect the transistor T.

The display element layer DPL may include a light emitting element corresponding to a pixel, a pixel definition layer PDL and a spacer SP.

A light emitting element of the first pixel R may include a first electrode EL1_R for the first pixel, an emission layer EML_R for the first pixel configured to emit red light and a second electrode EL2 provided on the emission layer EML_R for the first pixel. The second electrode EL2 may be provided together over the first to third pixel R, G and B.

The first electrode EL1_R for the first pixel may be connected (e.g., coupled) to the pixel circuit unit PCL of the first pixel R through a first pixel contact hole H.

A light emitting element OLED_G (hereinafter, a second light emitting element) of the second pixel G may include a first electrode EL1_G for the second pixel, an emission layer EML_G for the second pixel configured to emit green light, and a second electrode EL2 provided on the emission layer EML_G for the second pixel. The structures of light emitting elements corresponding to the first pixel R and the third pixel B may be substantially the same as those of the light emitting element OLED_G, and therefore, the structures and corresponding components of the first pixel R and the third pixel B may be understood by referring to FIG. 2.

The first electrode EL1_G for the second pixel may be connected (e.g., coupled) to the transistor T provided in the pixel circuit unit PCL of the second pixel G through a second pixel contact hole H.

A light emitting element of the third pixel B may include a first electrode EL1_B for the third pixel, an emission layer EML_B for the third pixel configured to emit blue light, and a second electrode EL2 provided on the emission layer EML_B for the third pixel.

The first electrode EL1_B for the third pixel may be connected (e.g., coupled) to the pixel circuit unit PCL of the third pixel B through a third pixel contact hole H.

In an exemplary embodiment of the present disclosure, the first electrode EL1_R for the first pixel, the first electrode EL1_G for the second pixel and the first electrode EL1_B for the third pixel may be an anode, and the second electrode EL2 may be a cathode.

In a case where the light emitting element of the first pixel R, the second light emitting element OLED_G, and the light emitting element of the third pixel B are a front light emitting type (or kind) of an organic light emitting element, the first electrode EL1_R for the first pixel, the first electrode EL1_G for the second pixel and the first electrode EL1_B for the third pixel may be reflective electrodes. In this case, the second electrode EL2 may be a transmissive electrode.

The substrate 110 may include a light emitting region EMA corresponding to each of the light emitting element of the first pixel R, the second light emitting element OLED_G and the light emitting element of the third pixel B, and a non-emitting region NEMA except for the light emitting region EMA.

The pixel definition layer PDL may protrude from the substrate 110 along a boundary of the first to third pixel R, G, and B. The pixel definition layer PDL may include an opening that exposes a portion of the first electrode EL1_R for the first pixel, a portion of the first electrode EL1_G for the second pixel, and a portion of the first electrode EL1_B for the third pixel, respectively.

The pixel definition layer PDL may divide each of the first to third pixels R, G, and B into the light emitting region EMA and the non-emitting region NEMA. The pixel definition layer PDL may include an organic insulation layer formed of organic material. For example, the pixel definition layer PDL may be formed of at least one selected from polystyrene, polymethylmethacrylate (PMMA), polyacrylonitrile (PAN), polyimide (PA), polyimide (PI) polyarylether (PAE), heterocyclic polymer, parylene, epoxy, benzocyclobutene (BCB), siloxane-based resin, and silane-based resin.

A spacer SP may be provided in the non-emitting region NEMA. The spacer SP may include the same (e.g., substantially the same) material as the pixel definition layer PDL and may be provided integrally with the pixel definition layer PDL. The spacer SP may be provided to prevent or reduce degradation of the characteristics of the light emitting element of the first pixel R, the second light emitting element OLED_G and the light emitting element of the third pixel G by an external impact. The spacer SP may be regularly or irregularly arranged in the display region DA.

The second electrode EL2 may be provided on the corresponding emission layer in the light emitting region EMA and may be provided on the pixel definition layer PDL and the spacer SP in the non-emitting region NEMA.

The protective layer 130 may be provided on the second electrode EL2.

The protective layer 130 may include a single layer, or it may include a plurality of layers. The protective layer 130 may include a plurality of insulation layers covering the light emitting elements of the first pixel R, the second light emitting element OLED_G, and the light emitting elements of the third pixel B.

In some embodiments, the protective layer 130 may include a plurality of inorganic layers and a plurality of organic layers. For example, the protective layer 130 may have a structure in which inorganic layers and organic layers are alternately stacked. In addition, in some cases, the protective layer 130 may be an encapsulation substrate bonded to the substrate 110 through a sealant.

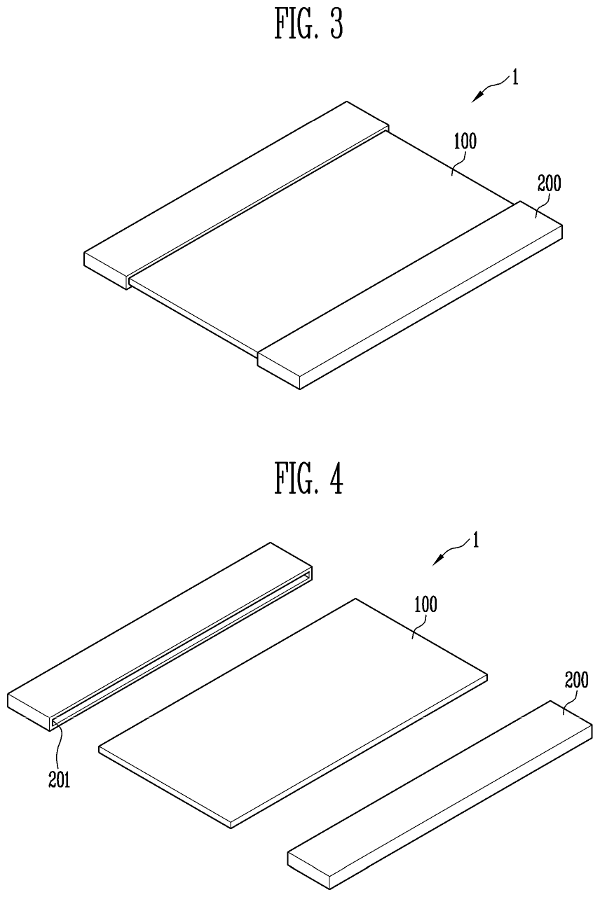

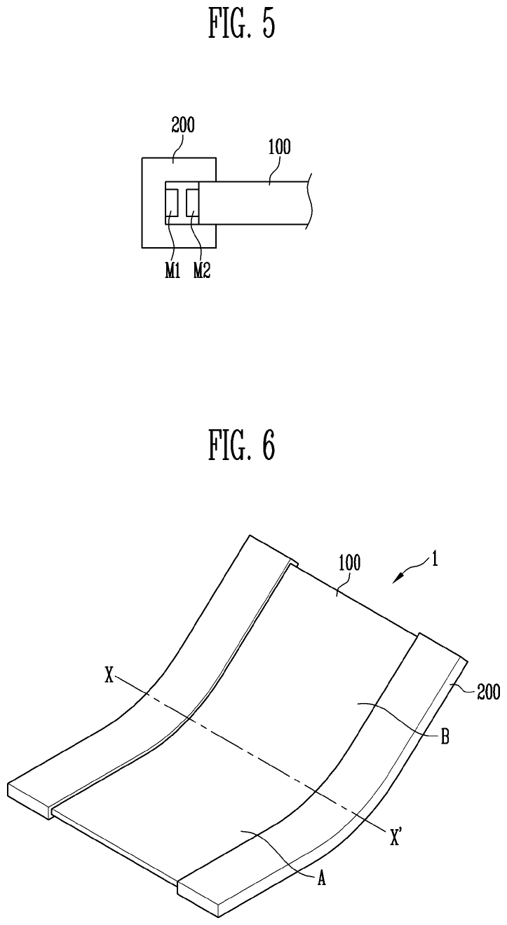

FIG. 3 is a perspective view of a flexible display device according to a first exemplary embodiment of the present disclosure, FIG. 4 is an exploded perspective view of a flexible display device according to a first exemplary embodiment of the present disclosure, and FIG. 5 is an enlarged cross-sectional view of a portion of a flexible display device according to a first exemplary embodiment of the present disclosure.

Referring to FIGS. 3-5, the flexible display device 1 may include a flexible display panel 100 and a driving module unit 200.

The flexible display panel 100 may include a display unit on a flexible substrate and a protective layer covering the display unit. The structure of the flexible display panel 100 may be the same (e.g., substantially the same) as the structure described in FIG. 1, and duplicative detailed description thereof is not repeated here.

The driving module unit 200 is detachably coupled to the at least one side of the flexible display panel 100. For example, the driving module unit 200 may be coupled to a longer side of the sides of the flexible display panel 100, but the present disclosure is not limited thereto. FIGS. 2 and 3 show an example in which the driving module unit 200 is coupled to the longer both sides of the flexible display panel 100. At this time, a length of the driving module unit 200 may be set to correspond to a length of the side of the flexible display panel 100 to be coupled.

The driving module unit 200 may be coupled to the flexible display panel 100 by an insertion coupling method (e.g., a connector and a groove coupling method). In this embodiment, the driving module unit 200 has an accepting portion 201 capable of accepting at least a portion of the flexible display panel 100 and may be formed as shown in FIG. 3.

A width of the accepting portion 201 may be correspond to a thickness of the flexible display panel 100 such that the flexible display panel 100 accepted in the accepting portion 201 may be tightly fixed to the flexible display panel 100 when the driving module unit 200 is coupled to the flexible display panel 100. In an exemplary embodiment of the present disclosure, at least one coupling structure for increasing a coupling force with the flexible display panel 100 and/or a frictional force may be formed inside the accepting portion 201.

In an exemplary embodiment of the present disclosure, the coupling structure may include a magnet coupling module as shown in FIG. 5. In this exemplary embodiment of the present disclosure, a first magnet M1 having an N pole or S pole may be provided inside the driving module unit 200. In addition, a second magnet M2 having an opposite polarity to the first magnet, for example, an S pole or an N pole, may be provided at a position corresponding to the first magnet M1 outside the flexible display panel 100. In this exemplary embodiment, the driving module unit 200 and the flexible display panel 100 may be more tightly coupled by a magnetic force between the first magnet and the second magnet (e.g., more tightly than they would be coupled without the first magnet and the second magnet).

However, the coupling structure described in an exemplary embodiment of the present disclosure is not limited to the above, and the coupling force between the driving module unit 200 and the flexible display panel 100 may be improved by various suitable structures such as a groove, a pin, a notch, a protruding member, and a spring member.

In various exemplary embodiments of the present disclosure, the coupling type and the coupling structure between the driving module unit 200 and the flexible display panel 100 are not particularly limited, and the flexible display panel 100 and the driving module unit 200 may be coupled with each other by a set or arbitrary structure for preventing or reducing separation of the flexible display panel 100 and the driving module unit 200 from each other while the flexible display device 1 is used.

The driving module unit 200 may be formed of a flexible material such that the driving module unit 200 may be transformed together with the flexible display panel 100. For example, an outer case of the driving module unit 200 may be formed of a polymer resin such as PVC, HDPE, or epoxy resin. However, a material of the outer case is not limited to the above, and may be any suitable material that may be curved or bent freely by an external force.

In an exemplary embodiment of the present disclosure, the driving module unit 200 may generate a driving signal configured to control the light emission of the pixels of the display unit 120 provided in the flexible display panel 100. For this purpose, the driving module unit 200 may include a flexible circuit board. The flexible circuit board may be formed of a chip on film (COF).

The driving module unit 200 may generate a driving signal based on image data and a timing synchronizing signal and output the generated driving signal to the flexible display panel 100. The driving signal may include, for example, a data signal, a scan signal, a light emission control signal, and/or the like.

The driving module unit 200 may be electrically connected (e.g., electrically coupled) to the flexible display panel 100 to transfer the driving signal to the flexible display panel 100. For this purpose, at least one terminal may be formed in the accepting portion 201 of the driving module unit 200. In this embodiment of the present disclosure, a terminal corresponding to the terminal of the accepting portion 201 may be formed outside of the flexible display panel 100. The terminals of the driving module unit 200 and the flexible display panel 100 may be coupled in a connector-coupled type (e.g., a connector-coupled arrangement), but the present disclosure is not limited thereto.

In an exemplary embodiment of the present disclosure, the driving module unit 200 may receive various sensing signals from a transformation sensing module, a resistance sensing module, and a pressure sensing module of the flexible display panel 100. For example, the driving module unit 200 may receive a sensing signal indicating an electric characteristic of a pixel circuit or an organic light emitting diode from a display unit 120 of the flexible display panel 100. In some embodiments, the driving module unit 200 may receive a sensing signal indicating information about a touch and/or a pressure applied to the flexible display panel 100 from the display unit 120. Here, the pressure may be applied to the flexible display panel 100 by bending the flexible display panel 100, and the driving module unit 200 may sense a bending state of the flexible display panel 100, for example, a bending position, a bending direction, a bending angle, and/or the like, from the sensing signal.

When the driving module unit 200 is separated from the flexible display panel 100, the driving signal is not transmitted from the driving module unit 200, to the flexible display panel 100 such that the flexible display panel 100 is switched to a non-driving state. A user may bend, fold or roll the separate driving module unit 200 and the flexible display panel 100 to keep them in a reduced volume.

In an exemplary embodiment, the driving module unit 200 may further include at least one hardware module. The hardware module may include, for example, a speaker, a microphone, a camera, an infrared (IR) lamp, a sensor, and/or the like.

Here, the sensor may include a three-axis sensor, a gyro sensor, a gravity sensor, an acceleration sensor, and/or the like configured to sense the disposal state of the flexible display device 1. The disposal state may include a three-axis rotation direction, a three-axis rotation angle, and/or the like of the flexible display device 1.

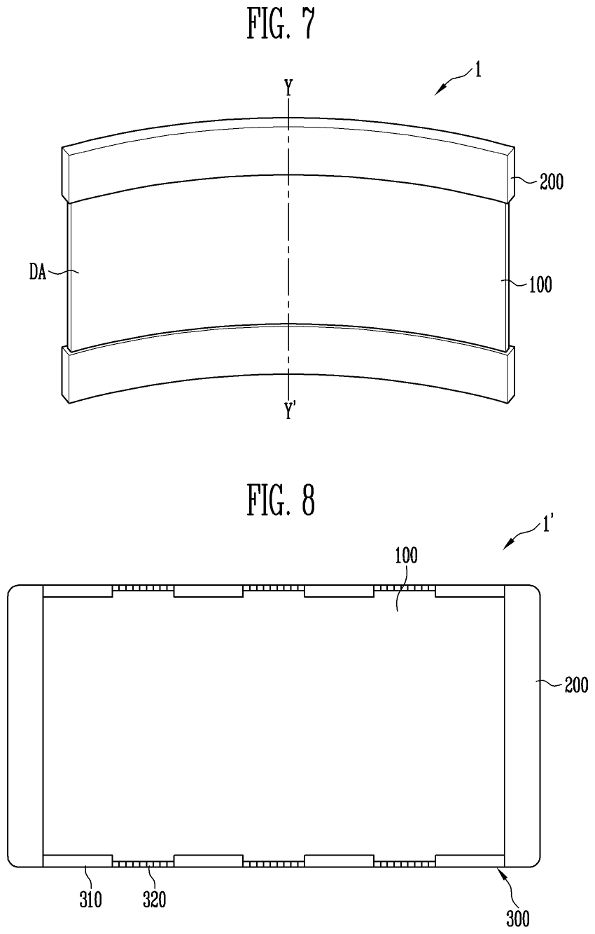

The driving module unit 200 may control an image to be displayed on the flexible display panel 100 in response to a rotational direction and/or a bending state of the flexible display device 1. An exemplary embodiment in which the driving module unit 200 is configured to control an image to be displayed on the flexible display panel 100 is shown in FIGS. 6 and 7.

FIG. 6 is a drawing showing a first use state of a flexible display device according to a first exemplary embodiment of the present disclosure.

In an exemplary embodiment shown in FIG. 6, the flexible display panel 100 and the driving module unit 200 remain coupled with each other. The flexible display panel 100 is bent along an arbitrary axis X-X′ vertical to both sides to which the driving module unit 200 is coupled. As the flexible display panel 100 is bent, the driving module unit 200 coupled to the flexible display panel 100 is bent together.

In addition, as shown in FIG. 6, a first region A of the flexible display panel 100 forms a flat portion parallel to (e.g., substantially parallel to) the ground, and a second region B of the flexible display panel 100 forms a flat portion which forms an arbitrary angle (e.g., 30° to 90°) with respect to a bending axis (X-X′), corresponding to the disposal state of the flexible display device 1.

The driving module unit 200 may receive a sensing signal from at least one module included in the flexible display panel 100 to sense the bending state and the disposal state of the flexible display panel 100. In an exemplary embodiment shown in FIG. 4, the driving module unit 200 may generate a driving signal to display a different image in the first region A and the second region B and transmit the driving signal to the flexible display panel 100.

In an exemplary embodiment, the driving module unit 200 may control the flexible display panel 100 to display a keypad image in the first region A and a content image of an application in the second region B. The content image may include, for example, a chat window, a multimedia image, a document creation page, a web page, and/or the like.

The flexible display device 100 may display an image corresponding to each of the first region A and the second region B based on the driving signal transferred from the driving module unit 200.

FIG. 7 is a drawing showing a second usage state of a flexible display device according to a first exemplary embodiment of the present disclosure.

In an exemplary embodiment of FIG. 7, the flexible display panel 100 and the driving module unit 200 remain coupled with each other. The flexible display panel 100 is bent along an arbitrary axis (Y-Y′) vertical to both sides to which the driving module unit 200 coupled. At this time, a bending angle of the flexible display panel 100 may be more gradual than a bending angle of the exemplary embodiment of FIG. 4. As the flexible display panel 100 is bent, the driving module unit 200 coupled to the flexible display panel 100 is bent together.

In addition, as shown in FIG. 7, a front surface DA of the flexible display panel 100 forms a set or arbitrary angle (e.g., 30° to 90°) with the ground (e.g., the surface of the Earth), corresponding to the disposal state of the flexible display device 1. At this time, the flexible display panel 100 may be arranged such that a longer side thereof faces downward.

In this exemplary embodiment, the driving module unit 200 may generate a driving signal such that an application content image is displayed on a whole surface of the flexible display panel 100 and transfers the driving signal to the flexible display panel 100. This driving state may be named an entire screen mode.

On the other hand, in an exemplary embodiment of FIG. 7, the driving module unit 200 is coupled to longer both sides of the flexible display panel 100, but an exemplary embodiment of the present disclosure is not limited thereto. In another exemplary embodiment, the driving module unit 200 may be coupled to at least one shorter side of the flexible display panel 100.

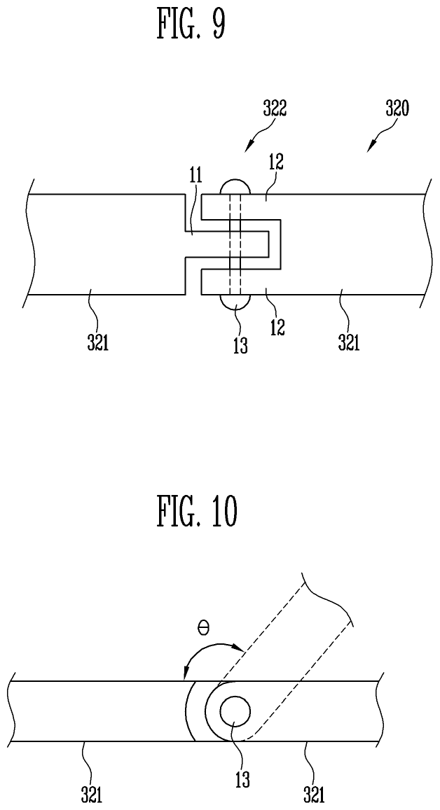

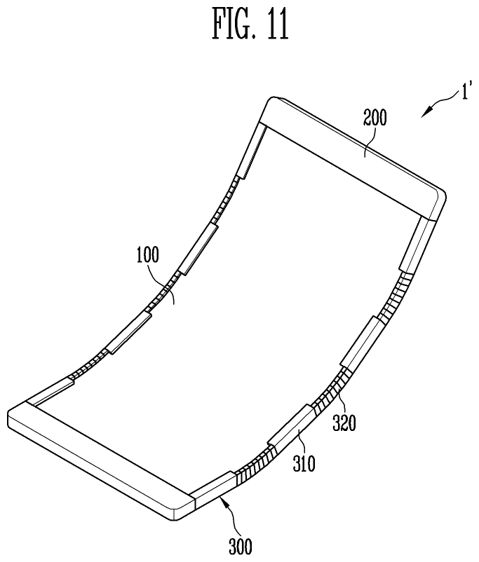

FIG. 8 is a plan view of a flexible display device according to the second exemplary embodiment of the present disclosure, FIGS. 9 and 10 are is a partial enlarged view of a panel bending unit shown in FIG. 8, and FIG. 11 is a drawing showing an example of a bending state of a flexible display device according to a second exemplary embodiment of the present invention.

Referring to FIGS. 8-11, a flexible display device 1′ may include a flexible display panel 100 and a driving module unit 200.

The flexible display panel 100 may include a display unit on a flexible substrate and a protective layer covering the display unit. The structure of the flexible display panel 100 may be the same (e.g., substantially the same) as the structure described in FIGS. 1 and 2, and duplicative detailed description thereof is not repeated here.

The driving module unit 200 is detachably coupled to the at least one side of the flexible display panel 100. For example, the driving module unit 200 may be coupled to a shorter side of the flexible display panel 100. FIG. 8 shows an example in which the driving module unit 200 is coupled to the shorter both sides of the flexible display panel 100.

The driving module unit 200 may generate a driving signal based on image data and a timing synchronizing signal and output the generated driving signal to the flexible display panel 100. The driving signal may include, for example, a data signal, a scan signal, a light emission control signal, and/or the like. The structure of the driving module unit 200 and a connection between the driving module unit 200 and the flexible display panel 100 may be the same (e.g., substantially the same) as the structure described in FIGS. 3-5, and duplicative detailed description thereof is not repeated here.

In a second exemplary embodiment of the present disclosure, the flexible display device may further include a panel bending unit 300.

The panel bending unit 300 may be coupled to at least one side of the flexible display panel 100. For example, the panel bending unit 300 may be coupled to a longer side of the flexible display panel 100. FIG. 8 shows an example in which the panel bending unit 300 is coupled to longer both sides of the flexible display panel 100. At this time, a length of the panel bending unit 300 may be set to correspond to a length of the side of the flexible display panel 100 to be coupled.

The panel bending unit 300 may include a coupling part 310 and a joint part 320, which are alternately arranged.

The coupling part 310 is coupled to the flexible display panel 100. In an exemplary embodiment, the coupling part 310 may extend along the side of the flexible display panel 100 to be coupled, and a cross section of the coupling part 310 may have a quadrangular shape, a rectangular shape, a semicircular shape, or a ‘=’ shape. When the cross section of the coupling part 310 is quadrangular, rectangular, semicircular shape, or the like, the cross section of the coupling part 310 may be in contact with the flexible display panel 100. When the cross section is ‘=’ shaped, the flexible display panel 100 may be inserted and coupled into the coupling part 310.

The coupling part 310 may be attached to the flexible display panel 100 using an adhesive or the like so that the coupling part 310 may not be separated from the flexible display panel 100. In exemplary embodiment of the present disclosure, the coupling part 310 may be formed of a rigid material or may be formed of a flexible material.

The joint part 320 may be provided between the coupling parts 310. In an exemplary embodiment of the present disclosure, the joint part 320 may be not directly coupled to the flexible display panel 100 and may be indirectly coupled to the flexible display panel 100 through the coupling part 310. For example, in this exemplary embodiment of the present disclosure, the joint part 320 may be adjacent to the side of the flexible display panel 100. However, the technical features of the present disclosure are not limited thereto, and the joint part 320 may be configured to couple directly to the flexible display panel 100.

The joint part 320 may be constructed with a hinged, multi-jointed structure. For example, the joint part 320 may include a plurality of supporters 321 arranged side by side and a plurality of hinge coupling parts 322 coupling the supporters 321 adjacent to each other.

The plurality of supporters 321 may be formed to have a rod shape that extends along the side of the flexible display panel 100 to be coupled and may be integrally coupled by a hinge coupling part 322. For example, the hinge coupling part 322 may include a first link arm 11 protruded from the side of one of the supporters 321 adjacent to each other, a second link arm 12 protruded from the side of the other supporter 321, and a fixing pin 13 for hinging the first link arm 11 and the second link arm 12 passing through the first link arm 11 and the second link arm 12. The supporters 321 adjacent to each other may rotate about the fixing pin 13, and thus, an angle (θ) between adjacent ones of the supporters 321 may change. A joint motion of the joint part 320 is performed as the angle (θ) between adjacent one of the supporters 321 changes.

By bending or unfolding the joint part 320 according to the joint motion, the flexible display panel 100 coupled to the panel bending unit 300 may be bent or unfolded. Referring to FIG. 11, the flexible display panel 100 may be bent according to the joint motion of the joint part 320 in an region adjacent to the joint part 320.

Meanwhile, the flexible display panel 100 may be not bent in a region directly coupled to the coupling part 310. However, in an exemplary embodiment of the present disclosure, when the coupling part 310 is formed of a flexible material, the flexible display panel 100 may be bent according to a deformation of the coupling part 310. In this exemplary embodiment of the present disclosure, by bending the coupling part 310, the coupling part 310 may have a more gradual deformation than the joint motion of the joint part 320, but the present disclosure is not limited thereto.

As used herein, the terms “substantially,” “about,” and similar terms are used as terms of approximation and not as terms of degree, and are intended to account for the inherent deviations in measured or calculated values that would be recognized by those of ordinary skill in the art. Further, the use of “may” when describing embodiments of the present disclosure refers to “one or more embodiments of the present disclosure.” As used herein, the terms “use,” “using,” and “used” may be considered synonymous with the terms “utilize,” “utilizing,” and “utilized,” respectively. Also, the term “exemplary” is intended to refer to an example or illustration.

Also, any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

Those with ordinary skill in the technical field of the present disclosure pertains will be understood that the present disclosure can be carried out in other forms without changing the technical idea or essential features. The exemplary embodiments should be considered in descriptive sense only and not for purposes of limitation. The disclosed embodiments should be considered in descriptive sense only and not for purposes of limitation. Therefore, the scope of the disclosure is defined not by the detailed description of the disclosure but by the appended claims, and all differences within the scope will be construed as being included in the present disclosure.

What is claimed is:

1. A flexible display device comprising:
a flexible display panel configured to display an image;
a driving module unit configured to transfer a driving signal to the flexible display panel and that is detachably fixedly coupled to at least a first side of the flexible display panel; and
a panel bending unit coupled to at least a second side of the flexible display panel,
wherein the panel bending unit comprises:
a plurality of coupling parts fixedly coupled to the flexible display panel; and
a plurality of joint parts between the plurality of coupling parts and having a hinged multi-jointed structure.

2. The flexible display device of claim 1, wherein the plurality of coupling parts are attached to the flexible display panel using an adhesive.

3. The flexible display device of claim 1, wherein the plurality of joint parts are adjacent to the flexible display panel as the plurality of coupling parts are coupled to the flexible display panel.

4. The flexible display device of claim 2, wherein each of the plurality of joint parts comprises:
a plurality of supporters; and
a hinge coupling part, wherein the supporters that are adjacent to each other are coupled to each other by the hinge coupling part, and
wherein the hinge coupling part comprises:
a link arm that extends from a side of one of the supporters to the adjacent supporter; and
a plurality of fixing pins that hinge and pass through the link arms of the adjacent supporters.

5. The flexible display device of claim 1, wherein the driving module unit comprises at least one hardware module selected from speakers, microphones, cameras, infrared (IR) lamps, and sensors.

6. The flexible display device of claim 1, wherein the driving module unit comprises a first magnet on one side thereof to be coupled to the flexible display panel, and
wherein the flexible display panel comprises a second magnet that is on a side coupled to the driving module unit and has a polarity opposite to that of the first magnet.

7. The flexible display device of claim 1, wherein the driving module unit is configured to sense a bending and disposal state of the flexible display panel based on a sensing signal received from the flexible display panel.

8. The flexible display device of claim 7, wherein the driving module unit controls the flexible display panel such that a different image is displayed in a first region and a second region divided by a first axis when the flexible display panel is bent along the first axis.

9. The flexible display device of claim 7, wherein the driving module unit controls the flexible display panel such that an application content image is displayed on a front of the flexible display panel when the flexible display panel is bent along a second axis and forms a predetermined angle with respect to a ground.
